(19) United States
(12) Patent Application Publication
(10) Pub. No.: US 2026/0190488 A1
(43) Pub. Date: Jul. 2, 2026

(54) DISPLAY DEVICE

(71) Applicant: LG DISPLAY CO., LTD., Seoul (KR)

(72) Inventors: DaeHwan Kim, Paju-si (KR); Jaeyoon Park, Paju-si (KR); Dongyeon Kang, Paju-si (KR)

(21) Appl. No.: 19/303,285

(22) Filed: Aug. 18, 2025

(30) Foreign Application Priority Data
Dec. 31, 2024 (KR) 10-2024-0202596

(51) Int. Cl. H10D 86/40

(52) U.S. Cl. CPC H10D 86/441; H10D 86/423; H10D 86/451

(57) ABSTRACT

A display device includes a substrate, an active layer disposed on the substrate, a gate insulation layer disposed on the active layer, a first gate pattern disposed on the gate insulation layer, an interlayer insulation layer disposed on the first gate pattern, a second gate electrode disposed on the interlayer insulation layer and connected to the first gate pattern through a contact hole of the interlayer insulation layer, a source electrode connected to a portion of the active layer, and a drain electrode connected to another portion of the active layer. The first gate pattern may include a first gate electrode connected to the second gate electrode.

### CROSS-REFERENCE TO RELATED APPLICATION

Pursuant to 35 U.S.C. § 119(a), this application claims the benefit of an earlier filing date and right of priority to Korean Patent Application No. 10-2024-0202596, filed on December 31, 2024, the contents of which are incorporated by reference in their entirety.

### TECHNICAL FIELD

The present disclosure relates generally to a display device.

### BACKGROUND

Display devices are applied to various electronic devices, such as TVs, mobile phones, laptops, and tablets. Display devices include organic light emitting displays (OLEDs), which are self-emissive, and liquid crystal displays (LCDs), which require a separate light source.

An organic light emitting display device may include a plurality of pixels. Each of the plurality of pixels may include a light emitting element, a driving transistor for controlling the amount of driving current supplied from a power line to the light emitting element according to the voltage of a gate electrode, and a switching transistor for supplying the data voltage of a data line to the gate electrode of the driving transistor in response to the scan signal of the scan line.

### SUMMARY

[5] A display device according to implementations of the disclosure may include a substrate, an active layer disposed on the substrate, a gate insulation layer disposed on the active layer, a first gate pattern disposed on the gate insulation layer, an interlayer insulation layer disposed on the first gate pattern, a second gate electrode disposed on the interlayer insulation layer and connected to the first gate pattern through a contact hole of the interlayer insulation layer, a source electrode connected to a portion of the active layer, and a drain electrode connected to another portion of the active layer. The first gate pattern may include a first gate electrode connected to the second gate electrode. A display device according to implementations of the disclosure may include a substrate, an active layer disposed on the substrate, a gate insulation layer disposed on the active layer, a first gate pattern disposed on the gate insulation layer, an interlayer insulation layer disposed on the first gate pattern, a second gate electrode disposed on the interlayer insulation layer and connected to the first gate pattern through a contact hole of the interlayer insulation layer, a source electrode connected to a portion of the active layer, and a drain electrode connected to another portion of the active layer. The active layer may include a first area including a dopant material. The first gate pattern may include a second area not overlapping the first area and a second sub area overlapping the first area. The concentration of oxygen vacancies in the second area may greater than the concentration of oxygen vacancies in the second sub area.

According to implementations of the disclosure, there may be provided a display device having a short gate electrode.

According to implementations of the disclosure, there may be provided a high-efficiency display device having a short channel length.

According to implementations of the disclosure, there may be provided a display device in which a plurality of transistors has uniform performance.

According to implementations of the disclosure, there may be provided a display device capable of preventing deterioration of a plurality of transistors.

According to implementations of the disclosure, there may be provided a display device having a transistor capable of preventing deterioration of element characteristics. Thus, the efficiency and lifespan of the display device may increase, reducing unnecessary power consumption, thereby allowing for low power consumption.

The effects of the disclosure are not limited to the foregoing objects, and other effects will be apparent to one of ordinary skill in the art from the following detailed description.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure. In the drawings:

FIG. 1 illustrates a display device according to implementations of the disclosure;

FIG. 2 illustrates a display panel according to an implementation of the disclosure;

FIG. 3 is a cross-sectional view illustrating a display panel according to implementations of the disclosure;

FIG. 4 is a plan view and cross-sectional view illustrating a display panel according to implementations of the disclosure;

FIG. 5 is a cross-sectional view taken along A-A’ and B-B’ of FIG. 4 in a display panel according to implementations of the disclosure;

FIG. 6 is a cross-sectional view illustrating a display panel according to implementations of the disclosure;

FIG. 7 is a cross-sectional view illustrating a display panel according to implementations of the disclosure;

FIG. 8 is a cross-sectional view illustrating a display panel according to implementations of the disclosure; and

FIGS. 9 to 13 are process cross-sectional views illustrating steps for forming the structure of FIG. 4 according to implementations of the disclosure.

### DETAILED DESCRIPTION

Modern electroluminescent display devices (e.g., active-matrix OLED (AMOLED) panels for smartphones, vehicle dashboards, and large-format TVs) often demand barrow bezels and higher pixel densities. In these form factors, parasitic resistance and capacitance in long metal interconnects can distort control signals, leading to non-uniform luminance, reduced aperture ratio due to oversized driver circuits, and increased power consumption during high-refresh-rate operation.

To address these limitations, implementations of display architectures disclosed herein embed first and second gate-driver blocks directly within the pixel array but staggers them along odd- and even-numbered column lines, respectively. A dedicated level-shifter circuit generates two non-overlapping clock signals that are phase-offset by one horizontal line period (1H). Separate clock lines route these phase-shifted signals to the corresponding gate drivers, thereby halving the effective capacitive load seen by each clock source and mitigating RC-induced timing skew across the panel.

By segregating the clock distribution network and alternately activating adjacent gate drivers, the architecture lowers simultaneous switching current, suppresses ground-bounce noise, and delivers more uniform gate-high voltages at the far edges of large or high-resolution substrates. Experimental results show that the proposed scheme maintains ≥99 % target gate voltage across 8K UHD panels while reducing driver power by up to 12 % relative to conventional single-clock topologies. Further aspects, implementations, and advantages of the disclosure will become apparent from the detailed description and accompanying drawings that follow.

According to an aspect of the present disclosure, a display panel architecture is disclosed in which first and second gate-driver blocks are embedded within the pixel array on alternating odd- and even-numbered column lines. The first and second gate-driver blocks are driven by two non-overlapping, phase-offset clock signals generated by an on-board level-shifter and routed through physically separate clock lines. This staggered topology halves the effective capacitive load on each clock path, suppresses RC-induced timing skew, and prevents simultaneous switching current from degrading gate-high levels, thereby preserving luminance uniformity, reducing driver power, and enabling narrow-bezel, high-resolution AMOLED and other electroluminescent displays. Implementations may include active-matrix panel (rigid or flexible) having a pixel array, a data driver for column voltages, two spatially alternating gate drivers that each receive a distinct clock, and a level-shifter or equivalent circuitry that produces the phase-shifted clocks. The disclosed display panel architecture may be used with different types of transistor technology (e.g., LTPS, LTPO, IGZO, oxide TFT) or dimensional scaling used to implement the drivers and clock lines.

Implementations of the disclosure may provide a display device having a short gate electrode.

Implementations of the disclosure may provide a high-efficiency display device having a short channel length.

Implementations of the disclosure may provide a display device in which a plurality of transistors have uniform performance.

Implementations of the disclosure may provide a display device capable of preventing deterioration of a plurality of transistors.

Objects of implementations of the disclosure are not limited to those set forth herein, and other unmentioned objects would be apparent to one of ordinary skill in the art from the following description.

In the following description of examples or implementations of the disclosure, reference will be made to the accompanying drawings in which it is shown by way of illustration specific examples or implementations that can be implemented, and in which the same reference numerals and signs can be used to designate the same or like components even when they are shown in different accompanying drawings from one another. Further, in the following description of examples or implementations of the disclosure, detailed descriptions of well-known functions and components incorporated herein will be omitted when it is determined that the description may make the subject matter in some implementations of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When a first element is described as being “connected or coupled to,” “contacts or overlaps” etc. a second element, it should be interpreted that, not only can the first element “be directly connected or coupled to” or “directly contact or overlap” the second element, but a third element can also be "interposed" between the first and second elements, or the first and second elements can “be connected or coupled to,” “contact or overlap”, etc. each other via a fourth element. Here, the second element may be included in at least one of two or more elements that "are connected or coupled to", “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an element or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various implementations of the disclosure are described in detail with reference to the accompanying drawings.

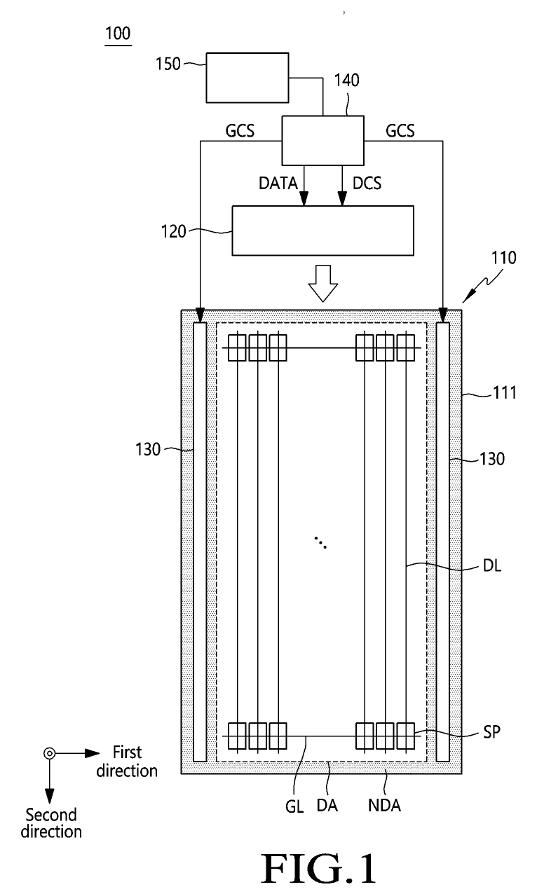

FIG. 1 illustrates a display device 100 according to implementations of the disclosure.

Referring to FIG. 1, a display device 100 according to implementations of the disclosure may include a display panel 110 and display driving circuits, as components for displaying images. The display driving circuit may be a circuit for driving the display panel 110. The display driving circuits may include a data driving circuit 120, a gate driving circuit 130, and a controller 140, but implementations of the disclosure are not limited thereto.

The display panel 110 may include a substrate 111 and a plurality of subpixels SP disposed on the substrate 111.

The substrate 111 may include a display area DA and a non-display area NDA.

The display area DA is an area where images may be displayed, and may also be referred to as an active area. A plurality of subpixels SP for image display may be disposed in the display area DA. The non-display area NDA is an area where no image is displayed and may be an area outside the display area DA. The non-display area NDA may also be referred to as a bezel (or bezel area). The non-display area NDA may include a pad area (also referred to as a pad portion).

For example, the non-display area NDA may include a first non-display area around the display area DA, a second non-display area including a pad area, and a bending area between the first non-display area and the second non-display area.

In the pad area, a driving circuit may be connected or bonded (or attached). As the bending area is bent, the bending area and the second non-display area may be disposed behind the first non-display area to be invisible from the front. The first non-display area may have a very small size. Implementations of the disclosure are not limited thereto.

No or little change may be made to the non-display area NDA shown to the user when the user views the display device 100 from the front, but implementations of the disclosure are not limited thereto.

The display device 100 according to implementations of the disclosure may be a self-luminous display device in which the display panel 110 emits light by itself, but implementations of the disclosure are not limited thereto. When the display device 100 according to the implementations of the disclosure is a self-emission display device, each of the plurality of subpixels SP may include a light emitting element.

For example, the display device 100 according to implementations of the disclosure may be an organic light emitting diode display in which the light emitting element is implemented as an organic light emitting diode (OLED). As another example, the display device 100 according to implementations of the disclosure may be an inorganic light emitting display device in which the light emitting element is implemented as an inorganic material-based light emitting diode. As another example, the display device 100 according to implementations of the disclosure may be a quantum dot display device in which the light emitting element is implemented as a quantum dot which is self-emission semiconductor crystal. As another example, the display device 100 according to implementations of the disclosure may be a micro LED display device or a mini LED display device.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors, but implementations of the disclosure are not limited thereto.

Various types of signal lines for driving a plurality of subpixels SP may be disposed on the substrate 111 of the display panel 110. For example, various types of signal lines may include a plurality of data lines DL transferring data signals (also referred to as data voltages or image signals) to a plurality of subpixels SP and a plurality of gate lines GL transferring gate signals (also referred to as scan signals) to the plurality of subpixels SP.

The plurality of data lines DL and the plurality of gate lines GL may cross each other. Each of the plurality of gate lines GL may be disposed to extend in a first direction (e.g., a row direction or column direction). Each of the plurality of data lines DL may be disposed to extend in a second direction (e.g., a column direction or row direction) different from the first direction.

In implementations of the disclosure, the angle between the first direction and the second direction may be 90 degrees or may an angle different from 90 degrees.

The data driving circuit 120 may be a circuit for driving the plurality of data lines DL, and may output data signals to the plurality of data lines DL.

The data driving circuit 120 may receive digital image data DATA from the controller 140 and may convert the received image data DATA into analog data signals (or also referred to as data voltages) and output them to the plurality of data lines DL.

In the display device 100 according to implementations of the disclosure, the gate driving circuit 130 may be embedded, in a gate in panel (GIP) type, in the display panel 110, but implementations of the disclosure are not limited thereto.

The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be substantially identical. As another example, the first semiconductor material and the second semiconductor material may be different from each other. For example, the first semiconductor material may be a silicon-based semiconductor material (e.g., low temperature poly silicon), and the second semiconductor material may be an oxide semiconductor material. For example, the active layer may be, but is not limited to, a semiconductor layer.

The controller 140 is a device for controlling the data driving circuit 120 and the gate driving circuit 130 and may control driving timings for the plurality of data lines DL and driving timings for the plurality of gate lines GL.

The controller 140 may receive input image data from the host system 150 and supply image data DATA to the data driving circuit 120 based on the input image data.

The display device 100 according to implementations of the disclosure may be a mobile terminal, such as a smart phone or a tablet, or a monitor or television (TV) in various sizes but is not limited thereto, and may be a display in various types and various sizes capable of displaying information or images.

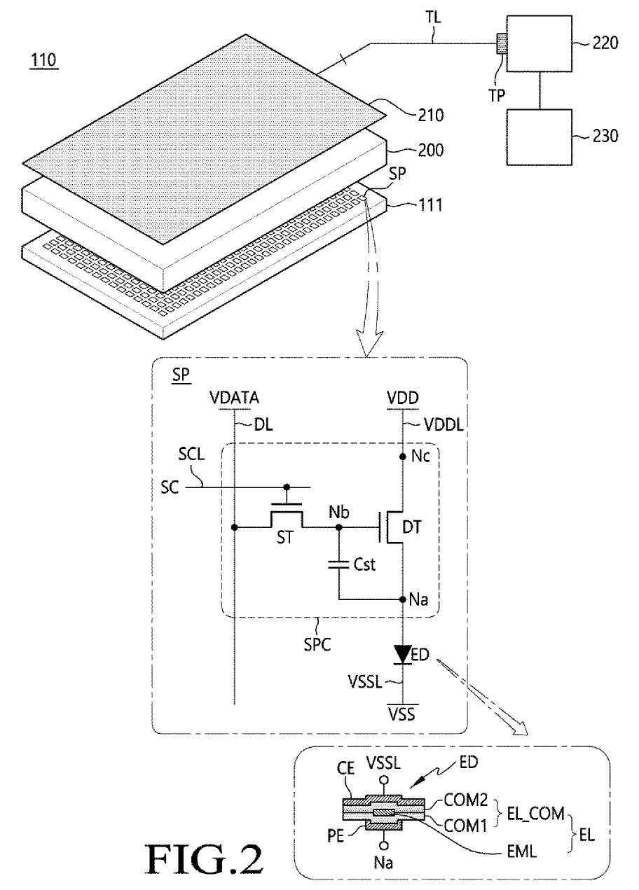

FIG. 2 illustrates a display panel 110 according to an implementation of the disclosure.

Referring to FIG. 2, the display panel 110 according to implementations of the disclosure may include a substrate 111 on which a plurality of subpixels SP are disposed and an encapsulation layer 200 on the substrate 111. The encapsulation layer 200 may also be referred to as an encapsulation substrate or an encapsulation unit.

Referring to FIG. 2, when the display device 100 according to implementations of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but implementations of the disclosure are not limited thereto. In the disclosure, the subpixel circuit SPC may drive the light emitting element ED by supplying a driving current to the light emitting element ED at a predetermined timing. The light emitting element ED may be driven by a driving current to emit light.

The plurality of transistors may include a driving transistor DT for driving the light emitting element ED and a scan transistor ST that is turned on or off according to the scan signal SC.

The driving transistor DT may supply a driving current to the light emitting element ED. The scan transistor ST may be configured to control the electrical state of a corresponding node in the subpixel circuit SPC or to control the state or operation of the driving transistor DT. The at least one capacitor may include a storage capacitor Cst for maintaining a constant voltage during a frame.

To drive the subpixel SP, a data signal VDATA as an image signal and a scan signal SC which is a type of gate signal may be applied to the subpixel SP. Further, for driving the subpixel SP, a common driving signal including the driving voltage VDD and the base voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all the subpixels SP. For example, the pixel electrode PE may be an anode, and the common electrode CE may be a cathode. As another example, the pixel electrode PE may be a cathode, and the common electrode CE may be an anode. For convenience of description, an example is described in which the pixel electrode PE is an anode, and the common electrode CE is a cathode.

When the light emitting element ED is an organic light emitting element, the intermediate layer EL may include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 may be collectively referred to as a common intermediate layer EL_COM.

The light emitting layer EML may be disposed for each subpixel SP or may be disposed commonly over a plurality of subpixels SP. The common intermediate layer EL_COM may be commonly disposed across the plurality of subpixels SP, but implementations of the disclosure are not limited thereto.

In other words, the light emitting layer EML may be disposed for each emission area or disposed commonly across a plurality of emission areas. The common intermediate layer EL_COM may be commonly disposed across a plurality of emission areas and non-emission areas, but implementations of the disclosure are not limited thereto.

For example, the first common intermediate layer COM1 may include a hole injection layer (HIL), an electron blocking layer (EBL), and a hole transport layer (HTL), but implementations of the disclosure are not limited thereto. The second common intermediate layer COM2 may include an electron transport layer (ETL), a hole blocking layer (HBL), and an electron injection layer (EIL), but implementations of the disclosure are not limited thereto.

For example, the common electrode CE may be electrically connected to the base voltage line VSSL. The base voltage VSS, which is one type of the common voltage, may be applied to the common electrode CE through the base voltage line VSSL. The pixel electrode PE may be electrically connected directly or indirectly (through another transistor) to the first node Na of the driving transistor DT of each subpixel SP.

Each light emitting element ED may include portions where the pixel electrode PE, the light emitting layer EML in the intermediate layer EL, and the common electrode CE overlap. A predetermined light emitting area may be formed by each light emitting element ED. For example, the light emitting area of each light emitting element ED may include an overlapping area of the pixel electrode PE, the light emitting layer EML in the intermediate layer EL, and the common electrode CE.

The driving transistor DT may be a driving transistor for supplying a driving current to the light emitting element ED. The driving transistor DT may be connected between a driving voltage line VDDL and the light emitting element ED.

The driving transistor DT may include a first node Na, a second node Nb, and a third node Nc. The first node Na may be electrically connected to the light emitting element ED, the second node Nb may receive a data signal VDATA, and the third node Nc may receive a driving voltage VDD, which is another kind of common voltage, from the driving voltage line VDDL. The driving transistor DT may be connected between the first node Na and the third node Nc.

Hereinafter, for convenience of description, an example is described in which in the driving transistor DT, the second node Nb may be a gate node, the first node Na may be a source node, and the third node Nc may be a drain node, but implementations of the disclosure are not limited thereto.

The scan transistor ST included in the subpixel circuit SPC illustrated in FIG. 2 may be a switching transistor for transferring the data signal VDATA, which is an image signal, to the second node Nb, which is the gate node of the driving transistor DT.

The scan transistor ST may be controlled to be turned on and off by the scan signal SC, which is a kind of gate signal applied through the scan line SCL, which is a type of the gate line GL, to control electrical connection between the second node Nb of the driving transistor DT and the data line DL. The drain electrode or the source electrode of the scan transistor ST may be electrically connected to the data line DL, the source electrode or the drain electrode of the scan transistor ST may be electrically connected to the second node Nb of the driving transistor DT, and the gate electrode of the scan transistor ST may be electrically connected to the scan line SCL.

The storage capacitor Cst may be electrically connected between the first node Na and second node Nb of the driving transistor DT. The storage capacitor Cst may include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

The display panel 110 may have a top emission structure or a bottom emission structure. When the display panel 110 has a top emission structure, at least a portion of the subpixel circuit SPC may overlap at least a portion of the light emitting element ED in a vertical direction. Accordingly, the area of the emission area may increase and the aperture ratio may increase. When the display panel 110 has a bottom emission structure, the subpixel circuit SPC may not overlap the light emitting element ED in the vertical direction.

As illustrated in FIG. 2, the subpixel circuit SPC may have a 2T (Transistor)1C (Capacitor) structure including two transistors DT and ST and one capacitor Cst. In some cases, the subpixel circuit SPC may further include one or more transistors or may further include one or more capacitors.

Since the circuit elements (e.g., the light emitting element ED implemented as an organic light emitting diode (OLED) including an organic material) in each subpixel SP are vulnerable to external moisture or oxygen, the encapsulation layer 200 may be disposed on the display panel 110. The encapsulation layer 200 may prevent external moisture or oxygen from penetrating into circuit elements (e.g., the light emitting element ED). The encapsulation layer 200 may be configured in various forms so that the light emitting elements ED do not contact moisture or oxygen. For example, the encapsulation layer 200 may be constituted of two or more layers in which organic films and inorganic films are alternately stacked, but implementations of the disclosure are not limited thereto.

Referring to FIG. 2, a display device 100 according to implementations of the disclosure may include a touch sensor layer 210 in which a touch sensor is formed, and a touch sensing circuit that senses the touch sensor formed in the touch sensor layer 210 to determine the presence of a touch or touch coordinates, to provide a touch sensing function. Here, the touch sensor layer 210 may also be referred to as a touch unit or touch sensing unit.

For example, the touch sensing circuit may include a touch driving circuit 220 configured to drive and sense the touch sensor formed in the touch sensor layer 210 to generate and output touch sensing data, and a touch controller 230 configured to determine the presence of a touch or touch coordinates using the touch sensing data provided from the touch driving circuit 220.

When the touch sensor layer 210 is embedded in the display panel 110, the display panel 110 may further include, in addition to the plurality of touch electrodes corresponding to the touch sensors, a plurality of touch pads TP to which the touch driving circuit 220 is electrically connected, and a plurality of touch routing lines TL electrically connecting the plurality of touch electrodes and the plurality of touch pads TP.

The touch driving circuit 220 may supply a touch driving signal to at least one of the plurality of touch electrodes and may sense at least one of the plurality of touch electrodes to generate touch sensing data.

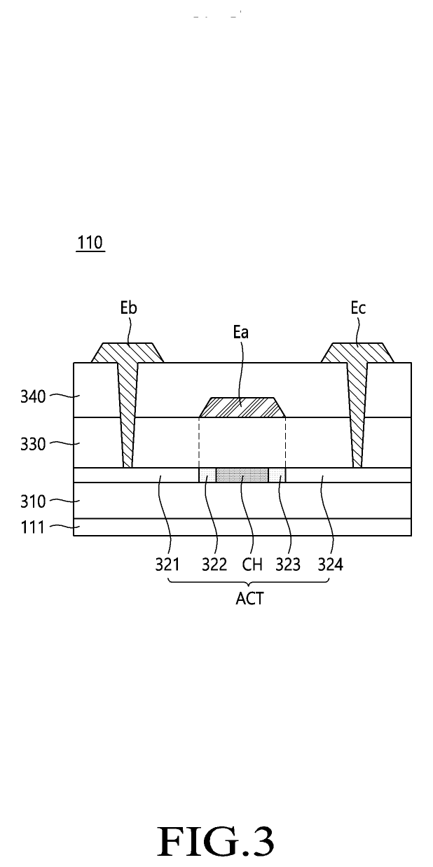

FIG. 3 is a cross-sectional view of a display panel 110 according to implementations of the disclosure.

Referring to FIG. 3, the display panel 110 according to implementations of the disclosure may include a substrate 111, a buffer layer 310, an active layer ACT, a gate insulation layer 330, a gate electrode Ea, an interlayer insulation layer 340, a source electrode Eb, and a drain electrode Ec, but the disclosure is not limited thereto.

The substrate 111 may be a single layer or multiple layers. When the substrate 111 is the multiple layers, the substrate 111 may include a first substrate, an intermediate substrate layer, and a second substrate. The intermediate substrate layer may be positioned between the first substrate and the second substrate. For example, each of the first substrate and the second substrate may be a polyimide (PI) layer, but implementations of the disclosure are not limited thereto. The intermediate substrate layer may be an inorganic insulation layer, but implementations of the disclosure are not limited thereto. When a charge is charged to the first substrate, which is a polyimide layer, the intermediate substrate layer may block the charge from affecting transistors disposed on the second substrate through the second substrate, which is a polyimide layer.

The buffer layer 310 may be disposed on the substrate 111. The buffer layer 310 may be a single layer or multiple layers, but implementations of the disclosure are not limited thereto. When the buffer layer 310 is multiple layers, the buffer layer 310 may include a lower buffer layer and an upper buffer layer.

The active layer ACT may be disposed on the buffer layer 310. The active layer ACT may include a semiconductor material. For example, the semiconductor material may include an oxide semiconductor, amorphous silicon, polysilicon, or low-temperature polysilicon (LTPS), but implementations of the disclosure are not limited thereto.

A partial area of the active layer ACT may include a dopant. The dopant may be impurity ions implanted into the active layer ACT through a doping method. A partial area of the active layer ACT including the dopant may function as a source area and/or a drain area, and the remaining area of the active layer ACT without the dopant may function as a channel area.

Referring to FIG. 3, the active layer ACT may include a channel portion CH where a channel is formed, a first conductive portion 321 connected to the source electrode Eb on one side of the channel portion CH, and a second conductive portion 324 connected to the drain electrode Ec on the other side of the channel portion CH. In other words, the first conductive portion 321 and the second conductive portion 324 may include a dopant.

The active layer ACT may further include a first diffusion portion 322 disposed between the first conductive portion 321 and the channel portion CH, and a second diffusion portion 323 disposed between the channel portion CH and the second conductive portion 324. The first diffusion portion 322 may be an area that extends toward the channel portion CH as a dopant is diffused from the first conductive portion 321 due to a concentration difference. The second diffusion portion 323 may be an area that extends toward the channel portion CH as a dopant is diffused from the second conductive portion 324 due to a concentration difference. Therefore, the first diffusion portion 322 and the second diffusion portion 323 may include a dopant, and the dopant concentrations of the first diffusion portion 322 and the second diffusion portion 323 may be smaller than or equal to the dopant concentration of the first and second conductive portions 321 and 324.

As the first diffusion portion 322 and the second diffusion portion 323 are formed, the length of the channel portion CH, i.e., the channel length of the transistor, may be shorter than a pre-designed value (hereinafter, the length by which the channel length of the transistor is shorter than the design value is referred to as “2ΔL”). Unlike the channel portion CH, the first diffusion portion 322 and the second diffusion portion 323 may not be controlled by a gate voltage applied to the gate electrode Ea. Thus, driving of the transistor may be difficult to control, or element characteristics may be deteriorated.

Referring to FIG. 3, a gate insulation layer 330 may be disposed on the active layer ACT. The gate electrode Ea may be disposed on the gate insulation layer 330, and the gate electrode Ea may overlap the first diffusion portion 322, the channel portion CH, and the second diffusion portion 323.

The interlayer insulation layer 340 may be disposed on the gate electrode Ea, and the source electrode Eb and the drain electrode Ec may be disposed on the interlayer insulation layer 340. The source electrode Eb and the drain electrode Ec may be connected to the first and second conductive portions 321 and 324, respectively, of the active layer ACT through holes of the interlayer insulation layer 340 and the gate insulation layer 330.

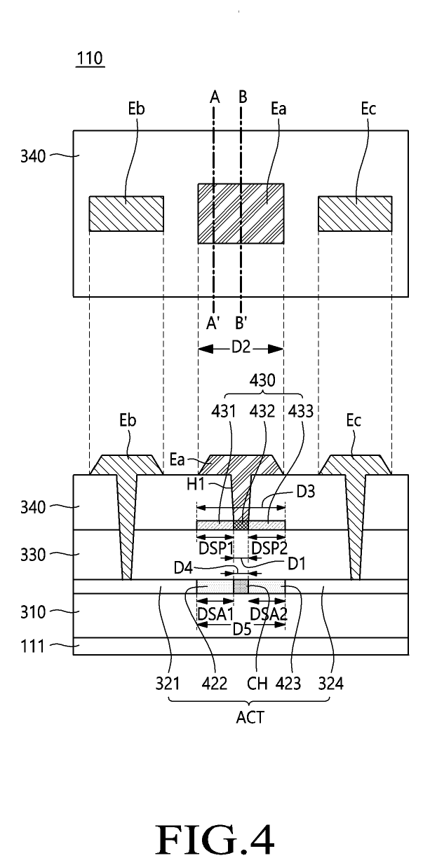

FIG. 4 is a plan view and cross-sectional view illustrating a display panel 110 according to implementations of the disclosure.

FIG. 4 may be a plan view and a cross-sectional view of at least one of a plurality of transistors disposed in the sub pixel circuit of the display panel 110 according to implementations of the disclosure.

Referring to the cross-sectional view of FIG. 4, the display panel 110 according to implementations of the disclosure may include a substrate 111, an active layer ACT disposed on the substrate 111, a gate insulation layer 330 disposed on the active layer ACT, a first gate pattern 430 disposed on the gate insulation layer 330, an interlayer insulation layer 340 disposed on the first gate pattern 430, a second gate electrode Ea disposed on the interlayer insulation layer 340 and connected to the first gate pattern 430 through a contact hole of the interlayer insulation layer 340, a source electrode Eb connected to a portion of the active layer ACT, and a drain electrode Ec connected to another portion of the active layer ACT.

The first gate pattern 430 may include a first gate electrode 432 connected to the second gate electrode Ea.

The size of the first gate electrode 432 may correspond to the size of the contact hole H1 formed in the interlayer insulation layer 340. As is described below, in the process of forming the display panel 110 according to implementations of the disclosure, a partial area of the first gate pattern 430 exposed when the contact hole is formed in the interlayer insulation layer 340 may be the first gate electrode 432. Therefore, the size of the first gate electrode 432 may correspond to the size of the lower end portion and/or the rear surface of the contact hole H1.

The first gate pattern 430 may include a first sub pattern 431 positioned on one side of the first gate electrode 432, and a second sub pattern 433 positioned on the other side of the first gate electrode 432.

The length D1 of the first gate electrode 432 may be larger than or equal to the length DSP1 of the first sub pattern 431 and the length DSP2 of the second sub pattern 433. For example, the length D1 of the first gate electrode 432 may be 1.5 to 2.2 μm, and the length DSP1 of the first sub pattern 431 and the length DSP2 of the second sub pattern 433 may be 0.5 μm. (In FIG. 4, considering the visibility of the first sub pattern 431 and the second sub pattern 433, the length DSP1 of the first sub pattern 431 and the length DSP2 of the second sub pattern 433 are shown larger than the length D1 of the first gate electrode 432.). The sum of the length D1 of the first gate electrode 432, the length DSP1 of the first sub pattern 431 and the length DSP2 of the second sub pattern 433 may be the length D3 of the first gate pattern 430.

The first gate pattern 430 may include an oxide semiconductor material, and the first gate electrode 432 may be a portion where the oxide semiconductor material is rendered conductive. The conductive first gate electrode 432 may function to correspond to the metal electrode in the transistor.

In the display panel 110 according to implementations of the disclosure, the oxide semiconductor material of the first gate pattern 430 may include at least one of indium-gallium-zinc oxide (IGZO), indium-gallium-zinc-tin oxide (IGZTO), and indium-gallium oxide (IGO), but the disclosure is not limited thereto. The oxide semiconductor material included in the first gate pattern 430 may be a material having lower electrical conductivity than a material such as molybdenum (Mo), aluminum (Al), or indium tin oxide (ITO).

Referring to FIG. 4, the active layer ACT may include a first conductive portion 321 connected to the source electrode Eb, a first sub conductive portion 422 overlapping at least a portion of the first sub pattern 431, a second conductive portion 324 connected to the drain electrode Ec, a second sub conductive portion 423 overlapping at least a portion of the second sub pattern 433, and a channel portion CH overlapping at least a portion of the first gate electrode 432.

Since the channel portion CH overlaps the first gate electrode 432, the channel portion CH may have a size corresponding to the size of the contact hole H1 formed in the interlayer insulation layer 340.

The length D4 of the channel portion CH may be larger than or equal to the length DSA1 of the first sub conductive portion 422 and the length DSA2 of the second sub conductive portion 423. For example, the length D4 of the channel portion CH may be 1.5 to 2.2 μm, and the length DSA1 of the first sub conductive portion 422 and the length DSA2 of the second sub conductive portion 423 may be 0.5 μm. (In FIG. 4, considering the visibility of the first sub conductive portion 422 and the second sub conductive portion 423, the length DSA1 of the first sub conductive portion 422 and the length DSA2 of the second sub conductive portion 423 are shown larger than the length D4 of the channel portion CH.). The sum of the length D4 of the channel portion CH, the length DSA1 of the first sub conductive portion 422 and the length DSA2 of the second sub conductive portion 423 may be D5.

In the display panel 110 according to implementations of the disclosure, the active layer ACT may include a first area including a dopant material, the first gate pattern 430 may include a second area not overlapping the first area and a second sub area overlapping the first area, and the concentration of oxygen vacancies in the second area may be greater than the concentration of oxygen vacancies in the second sub area.

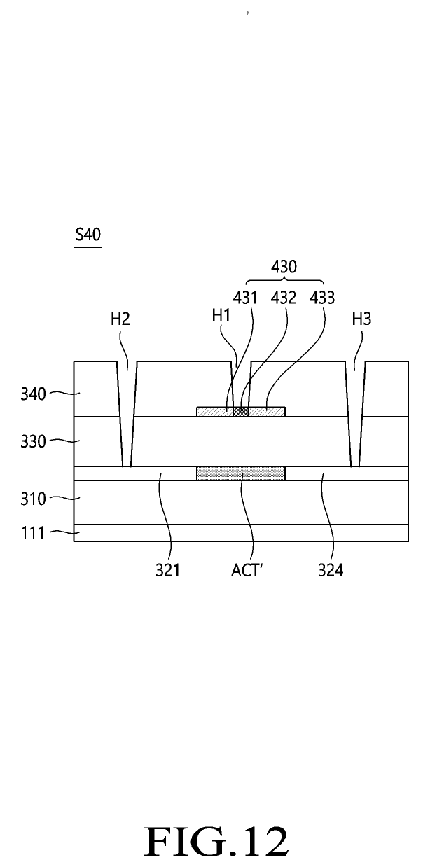

The second area may be connected to the second gate electrode Ea, and the second area may be an area where the oxide semiconductor material is rendered conductive. In other words, the second area may be the first gate electrode 432. As is described below with reference to FIG. 12, the first gate electrode 432 may be an area including a high proportion of oxygen vacancies.

The second area, i.e., the first gate electrode 432, may overlap the channel portion CH of the active layer ACT. Accordingly, the first area that does not overlap the second area may be an area except for the channel portion CH in the active layer ACT. Accordingly, the first area may be an area including the first conductive portion 321, the first sub conductive portion 422, the second conductive portion 324, and the second sub conductive portion 423 of the active layer ACT, and the first conductive portion 321, the first sub conductive portion 422, the second conductive portion 324, and the second sub conductive portion 423 may include the dopant material.

In the display panel 110 according to implementations of the disclosure, an area other than the first area of the active layer ACT may have an area corresponding to the second area of the first gate pattern 430. In other words, the channel portion CH may have an area corresponding to that of the first gate electrode 432.

In the display panel 110 according to implementations of the disclosure, the length D4 of the channel portion CH and the length D1 of the first gate electrode 432 may correspond to each other, the length DSA1 of the first sub conductive portion 422 and the length DSP1 of the first sub pattern 431 may correspond to each other, and the length DSA2 of the second sub conductive portion 423 and the length DSP2 of the second sub pattern 433 may correspond to each other.

In other words, the length D4 of the channel portion CH and the length D1 of the first gate electrode 432 may be the same, the length DSA1 of the first sub conductive portion 422 and the length DSP1 of the first sub pattern 431 may be the same, and the length DSA2 of the second sub conductive portion 423 and the length DSP2 of the second sub pattern 433 may be the same.

The first sub conductive portion 422 may include, in advance, an area that extends toward the channel portion CH as the dopant is diffused from the first conductive portion 321 due to a concentration difference. The second sub conductive portion 423 may include, in advance, an area that extends toward the channel portion CH as the dopant is diffused from the second conductive portion 324 due to a concentration difference. In other words, 2ΔL created by diffusion of the dopant may be formed in the first sub conductive portion 422 and the second sub conductive portion 423.

Accordingly, the formation of the first sub conductive portion 422 and the second sub conductive portion 423 in the display panel 110 according to implementations of the disclosure may not affect the length of the channel portion CH, i.e., the channel length of the transistor having a predetermined value.

As is described below, in the process of forming the display panel 110, the first and second conductive portions 321 and 324 may be formed by doping the active layer ACT with the dopant using the first gate pattern 430 as a mask.

Therefore, if the lengths of the first sub pattern 431 and the second sub pattern 433 are designed considering the diffusion of the dopant, the design value of the channel length may be accurately implemented.

For example, since the length of the channel portion CH is not shorter than the length of the first gate electrode 432, it is easy to control the driving of the transistor, and it is possible to prevent deterioration of element characteristics.

As another example, since the length of the channel portion CH is not larger than the length of the first gate electrode 432, an off-set area not overlapping the first gate electrode 432 may not be formed in the channel portion CH. Since the off-set area increases the resistance of the channel portion CH, when a transistor not including the off-set area is driven, control of the turn-on current may be enhanced.

In the display panel 110 according to implementations of the disclosure, the length D2 of the second gate electrode Ea may be larger than or equal to the length D1 of the first gate electrode 432. For example, the length D2 of the second gate electrode Ea may be 1.5 to 2.0 μm, and the length D1 of the first gate electrode 432 may be 1.2 to 1.5 μm.

As is described below, the first gate electrode 432 may be formed through a dry etching process for drilling a contact hole in the interlayer insulation layer 340. Since the contact hole is etched to have a size smaller than that of the second gate electrode Ea, the first gate electrode 432 may be formed to be smaller than the second gate electrode Ea. Accordingly, it may be easier to implement a short channel length in a transistor including the first gate electrode 432 than in a transistor including only the second gate electrode Ea.

As a result, since the length of the channel portion CH is shortened, the display panel 110 according to implementations of the disclosure may secure a high-efficiency transistor formed in the display area. Further, since the channel portion CH is not affected by the diffusion of the dopant, all of the plurality of transistors included in the display panel 110 according to implementations of the disclosure may secure uniform performance.

The plan view of FIG. 4 may illustrate upper surfaces of the interlayer insulation layer 340, the second gate electrode Ea, the source electrode Eb, and the drain electrode Ec. The second gate electrode Ea may be disposed between the source electrode Eb and the drain electrode Ec.

Referring to FIG. 4, both A-A′ and B-B′ are cut lines crossing the interlayer insulation layer 340 and the second gate electrode Ea.

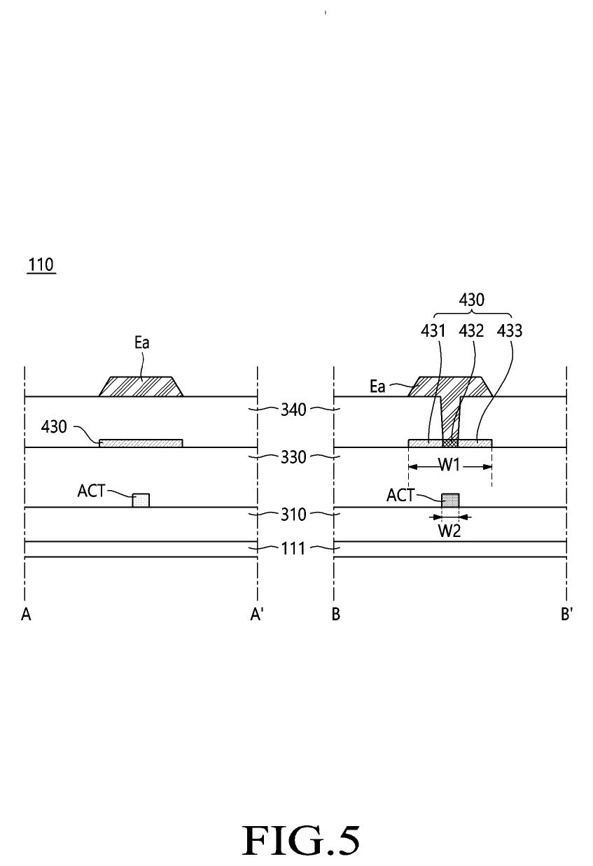

FIG. 5 is a cross-sectional view taken along A-A’ and B-B’ of FIG. 4 in a display panel 110 according to implementations of the disclosure.

Referring to FIG. 5, a display panel 110 according to implementations of the disclosure may include a substrate 111, a buffer layer 310, an active layer ACT, a gate insulation layer 330, a first gate pattern 430, an interlayer insulation layer 340, and a second gate electrode Ea.

Referring to FIG. 5, A-A′ may be a portion where the first gate electrode 432 and the second gate electrode Ea do not overlap.

In A-A′, the active layer ACT disposed on the buffer layer 310 may be a first sub conductive portion 422.

In A-A′, the first gate pattern 430 disposed on the gate insulation layer 330 may be a first sub pattern 431. The first sub pattern 431 may overlap the entirety of the second gate electrode Ea.

B-B′ may be a portion where the first gate electrode 432 and the second gate electrode Ea overlap.

In B-B′, the active layer ACT disposed on the buffer layer 310 may be a channel portion CH.

In B-B′, a first gate pattern 430 including a first gate electrode 432, a first sub pattern 431, and/or a second sub pattern 433 may be disposed on the gate insulation layer 330. The first gate electrode 432 may overlap a portion of the second gate electrode Ea.

Referring to FIG. 5, the width W1 of the first gate pattern 430 may be equal to or larger than the width W2 of the active layer ACT.

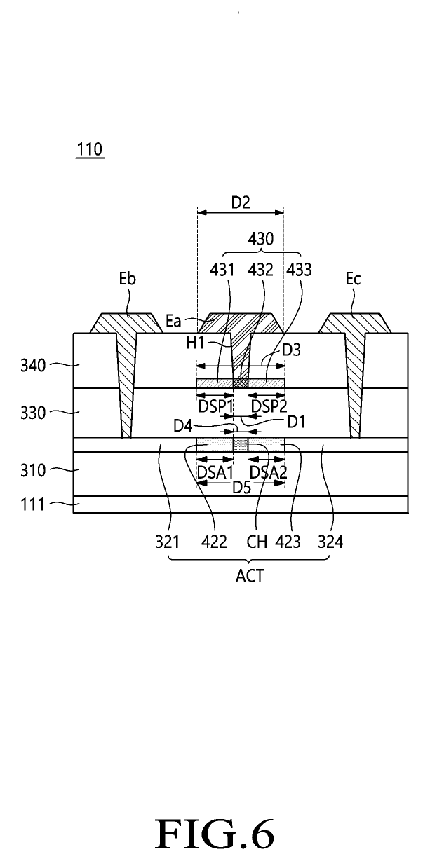

FIG. 6 is a cross-sectional view of a display panel 110 according to implementations of the disclosure.

Referring to FIG. 6, a display panel 110 according to implementations of the disclosure may include a substrate 111, a buffer layer 310, an active layer ACT, a gate insulation layer 330, a first gate pattern 430, an interlayer insulation layer 340, a second gate electrode Ea, a source electrode Eb, and a drain electrode Ec.

Referring to FIG. 6, the length DSA1 of the first sub conductive portion 422 may be larger than the length DSP1 of the first sub pattern 431, and the length DSA2 of the second sub conductive portion 423 may be larger than the length DSP2 of the second sub pattern 433.

For example, the length DSP1 of the first sub pattern 431 and the length DSP2 of the second sub pattern 433 may be smaller than 0.5 μm. The length DSA1 of the first sub conductive portion 422 and length DSA2 of the second sub conductive portion 423 may be larger than or equal to 0.5 μm.

Referring to FIG. 6, the length D4 of the channel portion CH may be smaller than the length D1 of the first gate electrode 432. Accordingly, a partial area of each of the first sub conductive portion 422 and the second sub conductive portion 423 may overlap the first gate electrode 432.

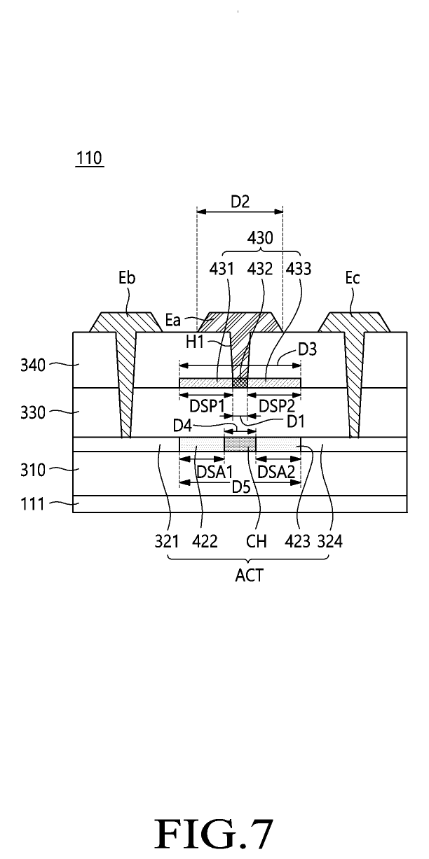

FIG. 7 is a cross-sectional view of a display panel 110 according to implementations of the disclosure.

Referring to FIG. 7, a display panel 110 according to implementations of the disclosure may include a substrate 111, a buffer layer 310, an active layer ACT, a gate insulation layer 330, a first gate pattern 430, an interlayer insulation layer 340, a second gate electrode Ea, a source electrode Eb, and a drain electrode Ec.

Referring to FIG. 7, the length DSA1 of the first sub conductive portion 422 may be smaller than the length DSP1 of the first sub pattern 431, and the length DSA2 of the second sub conductive portion 423 may be smaller than the length DSP2 of the second sub pattern 433.

For example, the length DSP1 of the first sub pattern 431 and the length DSP2 of the second sub pattern 433 may be larger than 0.5 μm. The length DSA1 of the first sub conductive portion 422 and the length DSA2 of the second sub conductive portion 423 may be equal to or smaller than 0.5 μm.

Referring to FIG. 7, the length D4 of the channel portion CH may be larger than the length D1 of the first gate electrode 432. Accordingly, a partial area of the channel portion CH may not overlap the first gate electrode 432.

Referring to FIG. 7, the length D2 of the second gate electrode Ea may be larger than or equal to the length D1 of the first gate electrode 432, and smaller than or equal to the length D3 of the first gate pattern 430.

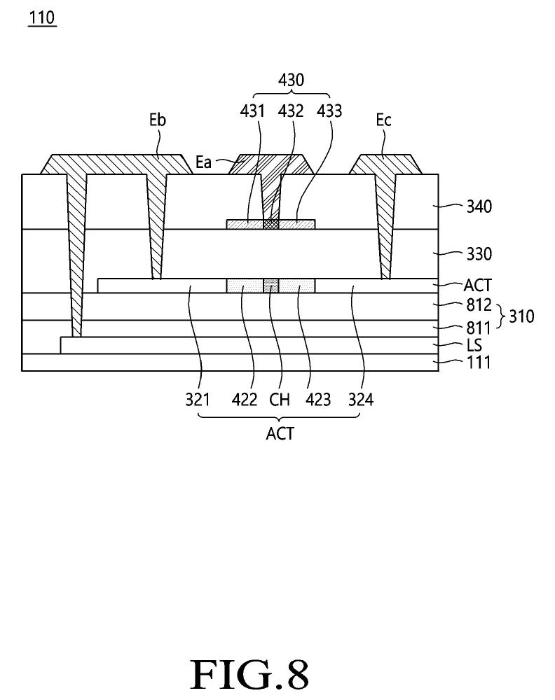

FIG. 8 is a cross-sectional view of a display panel 110 according to implementations of the disclosure.

Referring to FIG. 8, a display panel 110 according to implementations of the disclosure may include a substrate 111, a buffer layer 310, an active layer ACT, a gate insulation layer 330, a first gate pattern 430, an interlayer insulation layer 340, a second gate electrode Ea, a source electrode Eb, and a drain electrode Ec.

Referring to FIG. 8, the buffer layer 310 may be multiple layers. The buffer layer 310 may include a lower buffer layer 811 and an upper buffer layer 812.

Referring to FIG. 8, the display panel 110 according to implementations of the disclosure may further include a light blocking layer LS disposed between the substrate 111 and the lower buffer layer 811. The light blocking layer LS may be also disposed between the lower buffer layer 811 and the upper buffer layer 812.

At least a portion of the light blocking layer LS may be disposed to overlap the active layer ACT to block light incident on the active layer ACT.

The light blocking layer LS may function as at least one of a line and/or an electrode. In the example of FIG. 8, the light blocking layer LS may be electrically connected to the source electrode Eb.

Referring to FIG. 8, the source electrode Eb, the drain electrode Ec, and the second gate electrode Ea may all be disposed on the interlayer insulation layer 340.

Although not illustrated, the interlayer insulation layer 340 may be a single layer or multiple layers. For example, when the interlayer insulation layer 340 is multiple layers, it may include a lower interlayer insulation layer and an upper interlayer insulation layer. Accordingly, the arrangement of the source electrode Eb, the drain electrode Ec, and the second gate electrode Ea may be changed.

For example, the source electrode Eb and the drain electrode Ec may be disposed between the lower interlayer insulation layer and the upper interlayer insulation layer, and the second gate electrode Ea may be disposed on the upper interlayer insulation layer. As another example, the second gate electrode Ea may be disposed between the lower interlayer insulation layer and the upper interlayer insulation layer, and the source electrode Eb and the drain electrode Ec may be disposed on the upper interlayer insulation layer.

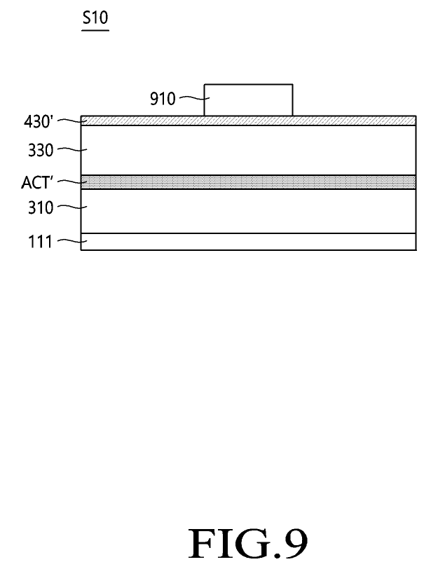

FIGS. 9 to 13 are process cross-sectional views illustrating steps for forming the structure of FIG. 4 according to implementations of the disclosure.

In the display panel 110 according to implementations of the disclosure, a buffer layer 310 may be formed on the substrate 111, a first semiconductor layer may be formed on the buffer layer 310, and a gate insulation layer 330 may be formed on the first semiconductor layer.

Referring to FIG. 9, a first step S10 may be a step of forming a second semiconductor layer 430’ on a gate insulation layer 330 and patterning a photoresist (PR) material in a partial area on the second semiconductor layer 430’ to form a PR pattern 910.

The second semiconductor layer 430’ may be etched using the PR pattern 910 as a mask. In other words, the remaining area of the second semiconductor layer 430’ except for the area overlapping the PR pattern 910 may be removed.

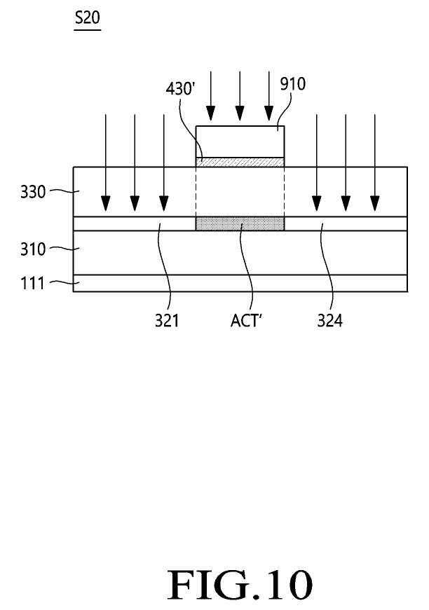

Referring to FIG. 10, a second step S20 may be a step of rendering a partial area of the first semiconductor layer ACT′ conductive.

The dopant may be injected into the front surface through a doping method. In the area of the first semiconductor layer ACT′ overlapping the PR pattern 910, the dopant may be blocked by the PR pattern 910 and thus fail to reach the first semiconductor layer ACT’. The dopant may be injected into an area not overlapping the PR pattern 910, i.e., an area not overlapping the second semiconductor layer 430’ in the first semiconductor layer ACT’, which may thus be rendered conductive. As the dopant is injected, the first conductive portion 321 and the second conductive portion 324 may be formed.

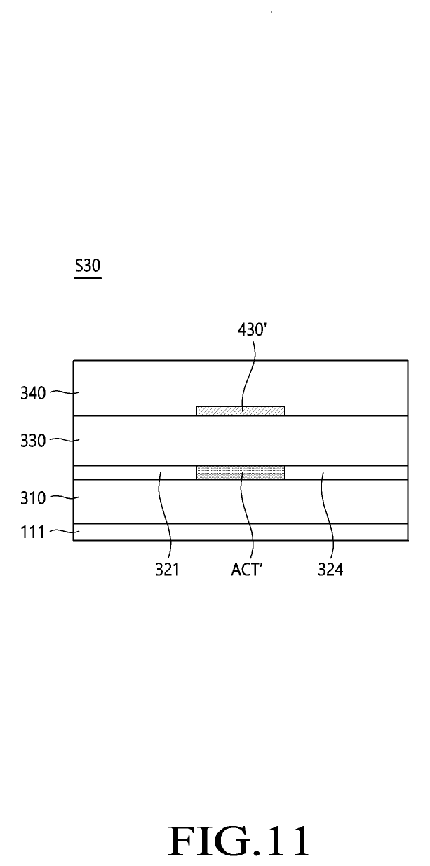

Referring to FIG. 11, a third step S30 may be a step of removing the PR pattern 910 and forming the interlayer insulation layer 340. The interlayer insulation layer 340 may be formed on the gate insulation layer 330 and the second semiconductor layer 430’.

Referring to FIG. 12, a fourth step S40 may be a step of forming first to third holes H1, H2, and H3 in the gate insulation layer 330 and the interlayer insulation layer 340 by an etching process.

The material of the interlayer insulation layer 340 may be etched through a dry etching process to form the first hole H1. A portion of the upper surface of the second semiconductor layer 430’ may be exposed by the first hole H1. As the dry etching process is continuous on the exposed upper surface of the second semiconductor layer 430’, a portion of the second semiconductor layer 430’ may be rendered conductive. In the second semiconductor layer 430’, a first gate pattern 430 including the conductive first gate electrode 432 and the non-conductive first sub pattern 431 and second sub pattern 433 may be formed. Hereinafter, a process of rendering a portion of the second semiconductor layer 430’ conductive is described in detail.

The second semiconductor layer 430’ including the oxide semiconductor material may be damaged by etching gas used in the dry etching process. In the damaged area of the second semiconductor area 430’, sites with missing oxygen (i.e., oxygen vacancies) may increase. The oxygen vacancies may increase the number of free carriers in the second semiconductor layer 430’ and decrease resistance.

Therefore, the area of the second semiconductor layer 430’ which has been rendered conductive by including a high proportion of oxygen vacancies may be the first gate electrode 432. In other words, the concentration of oxygen vacancies in the first gate electrode 432 may be greater than the concentration of oxygen vacancies in each of the first sub pattern 431 and the second sub pattern 433. A portion of the upper surface of the first conductive portion 321 may be exposed by the second hole H2 formed in the gate insulation layer 330 and the interlayer insulation layer 340. A portion of the upper surface of the second conductive portion 324 may be exposed by the third hole H3 formed in the gate insulation layer 330 and the interlayer insulation layer 340.

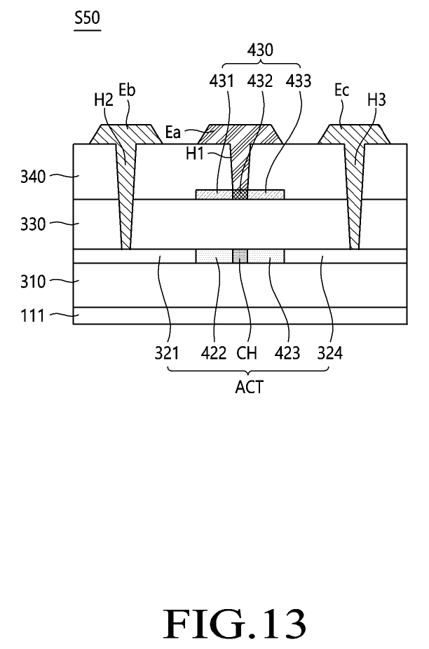

Referring to FIG. 13, a fifth step S50 may be a step of forming the second gate electrode Ea, the source electrode Eb, and the drain electrode Ec and forming the first sub conductive portion 422 and the second sub conductive portion 423.

The second gate electrode Ea, the source electrode Eb, and the drain electrode Ec may be disposed on the interlayer insulation layer 340, and may be formed inside the first hole H1, the second hole H2, and the third hole H3, respectively. Accordingly, the second gate electrode Ea may be connected to the first gate electrode 432, the source electrode Eb may be connected to the first conductive portion 321, and the drain electrode Ec may be connected to the second conductive portion 324.

For example, the source electrode Eb and the drain electrode Ec may include a metal material different from that of the second gate electrode Ea. As another example, the source electrode Eb and the drain electrode Ec may include the same metal material as the second gate electrode Ea.

The dopant included in the first conductive portion 321 and the second conductive portion 324 may be diffused into an area where the dopant is not injected due to a difference in concentration. In other words, the dopant may be diffused into an area overlapping the first gate pattern 430 in the first semiconductor layer ACT′. The dopant may be diffused to form the first sub conductive portion 422 on one side of the first conductive portion 321 and the second sub conductive portion 423 on the other side of the second conductive portion 324.

A channel portion CH which is not reached by the dopant may be formed between the first sub conductive portion 422 and the second sub conductive portion 423.

The active layer ACT including the first conductive portion 321, the first sub conductive portion 422, the channel portion CH, the second sub conductive portion 423, and the second conductive portion 324 may be formed in the first semiconductor layer ACT′.

A display device according to an implementation of the disclosure may be described as follows.

A display device according to implementations of the disclosure may include a substrate, an active layer disposed on the substrate, a gate insulation layer disposed on the active layer, a first gate pattern disposed on the gate insulation layer, an interlayer insulation layer disposed on the first gate pattern, a second gate electrode disposed on the interlayer insulation layer and connected to the first gate pattern through a contact hole of the interlayer insulation layer, a source electrode connected to a portion of the active layer, and a drain electrode connected to another portion of the active layer.

According to the display device according to implementations of the disclosure, the first gate pattern may include a first gate electrode connected to the second gate electrode.

According to the display device according to implementations of the disclosure, the first gate pattern may include an oxide semiconductor material, and the first gate electrode may be a portion in which the oxide semiconductor material may be rendered conductive.

According to the display device according to implementations of the disclosure, the oxide semiconductor material may include at least one of indium-gallium-zinc oxide (IGZO), indium-gallium-zinc-tin oxide (IGZTO), and indium-gallium oxide (IGO).

According to the display device according to implementations of the disclosure, a size of the first gate electrode may correspond to a size of the contact hole.

According to the display device according to implementations of the disclosure, the active layer may have a channel portion having a size corresponding to a size of the contact hole.

According to the display device according to implementations of the disclosure, a length of the second gate electrode may be larger than or equal to a length of a first gate electrode, and smaller than or equal to a length of the first gate pattern.

According to the display device according to implementations of the disclosure, the first gate pattern may include a first sub pattern positioned on one side of the first gate electrode and a second sub pattern positioned on another side of the first gate electrode.

According to the display device according to implementations of the disclosure, the length of the first gate electrode may be larger than or equal to a length of the first sub pattern and a length of the second sub pattern.

According to the display device according to implementations of the disclosure, the active layer may include a first conductive portion connected to the source electrode, a first sub conductive portion overlapping at least a portion of the first sub pattern, a second conductive portion connected to the drain electrode, a second sub conductive portion overlapping at least a portion of the second sub pattern, and a channel portion overlapping at least a portion of the first gate electrode.

According to the display device according to implementations of the disclosure, a length of the channel portion may be larger than or equal to a length of the first sub conductive portion and a length of the second sub conductive portion.

According to the display device according to implementations of the disclosure, a length of the channel portion and a length of the first gate electrode may correspond to each other, a length of the first sub conductive portion and a length of the first sub pattern may correspond to each other, and a length of the second sub conductive portion and a length of the second sub pattern may correspond to each other.

According to the display device according to implementations of the disclosure, a length of the channel portion may be smaller than the length of the first gate electrode, a length of the first sub conductive portion may be larger than a length of the first sub pattern, and a length of the second sub conductive portion may be larger than a length of the second sub pattern.

According to the display device according to implementations of the disclosure, a length of the channel portion may be larger than the length of the first gate electrode, a length of the first sub conductive portion may be smaller than a length of the first sub pattern, and a length of the second sub conductive portion may be smaller than a length of the second sub pattern.

According to the display device according to implementations of the disclosure, a width of the first gate pattern may be larger than or equal to a width of the active layer.

A display device according to implementations of the disclosure may include a substrate, an active layer disposed on the substrate, a gate insulation layer disposed on the active layer, a first gate pattern disposed on the gate insulation layer, an interlayer insulation layer disposed on the first gate pattern, a second gate electrode disposed on the interlayer insulation layer and connected to the first gate pattern through a contact hole of the interlayer insulation layer, a source electrode connected to a portion of the active layer, and a drain electrode connected to another portion of the active layer.

According to the display device according to implementations of the disclosure, the active layer may include a first area including a dopant material, the first gate pattern may include a second area not overlapping the first area and a second subarea overlapping the first area, and the concentration of oxygen vacancies in the second area may be greater than the concentration of oxygen vacancies in the second sub area.

According to the display device according to implementations of the disclosure, the second area may be connected to the second gate electrode.

According to the display device according to implementations of the disclosure, the first gate pattern may be formed of an oxide semiconductor material, and the second area may be an area in which the oxide semiconductor material may be rendered conductive.

According to the display device according to implementations of the disclosure, an area of the active layer other than the first area may have an area corresponding to the second area.

The above description has been presented to enable any person skilled in the art to make and use the technical idea of the disclosure, and has been provided in the context of a particular application and its requirements. Various modifications, additions and substitutions to the described implementations will be readily apparent to those skilled in the art, and the general principles defined herein may be applied to other implementations and applications without departing from the spirit and scope of the disclosure. The above description and the accompanying drawings provide an example of the technical idea of the disclosure for illustrative purposes only. That is, the disclosed implementations are intended to illustrate the scope of the technical idea of the disclosure.

1. A display device, comprising:
a substrate;
an active layer disposed on the substrate;
a gate insulation layer disposed on the active layer;
a first gate pattern disposed on the gate insulation layer;
an interlayer insulation layer disposed on the first gate pattern;
a second gate electrode disposed on the interlayer insulation layer and connected to the first gate pattern through a contact hole of the interlayer insulation layer;
a source electrode connected to a portion of the active layer; and
a drain electrode connected to another portion of the active layer,
wherein the first gate pattern includes a first gate electrode connected to the second gate electrode.

2. The display device of claim 1, wherein the first gate pattern includes an oxide semiconductor material, and
wherein the first gate electrode comprises a conductive portion of the oxide semiconductor material.

3. The display device of claim 2, wherein the oxide semiconductor material comprises at least one of indium-gallium-zinc oxide, indium-gallium-zinc-tin oxide, and indium-gallium oxide.

4. The display device of claim 1, wherein a size of the first gate electrode corresponds to a size of the contact hole.

5. The display device of claim 1, wherein the active layer has a channel portion sized to correspond to a size of the contact hole.

6. The display device of claim 1, wherein the first gate pattern comprises:
a first sub pattern positioned on a first side of the first gate electrode; and
a second sub pattern positioned on a second side of the first gate electrode,
wherein a length of the second gate electrode is greater than or equal to a length of the first gate electrode.

7. The display device of claim 6, wherein the length of the second gate electrode is smaller than or equal to the length of the first gate pattern.

8. The display device of claim 7, wherein the length of the first gate electrode is greater than or equal to a length of the first sub pattern and a length of the second sub pattern.

9. The display device of claim 7, wherein the active layer comprises:
a first conductive portion connected to the source electrode;
a first sub conductive portion overlapping at least a portion of the first sub pattern;
a second conductive portion connected to the drain electrode;
a second sub conductive portion overlapping at least a portion of the second sub pattern; and
a channel portion overlapping at least a portion of the first gate electrode.

10. The display device of claim 9, wherein a length of the channel portion is greater than or equal to a length of the first sub conductive portion and a length of the second sub conductive portion.

11. The display device of claim 9, wherein:
a length of the channel portion corresponds to a length of the first gate electrode,
a length of the first sub conductive portion corresponds to a length of the first sub pattern, and
a length of the second sub conductive portion corresponds to a length of the second sub pattern.

12. The display device of claim 9, wherein:
a length of the channel portion is smaller than the length of the first gate electrode,
a length of the first sub conductive portion is greater than a length of the first sub pattern, and
a length of the second sub conductive portion is greater than a length of the second sub pattern.

13. The display device of claim 9, wherein:
a length of the channel portion is greater than the length of the first gate electrode,
a length of the first sub conductive portion is smaller than a length of the first sub pattern, and
a length of the second sub conductive portion is smaller than a length of the second sub pattern.

14. The display device of claim 1, wherein a width of the first gate pattern is greater than or equal to a width of the active layer.

15. A display device, comprising:
a substrate;
an active layer disposed on the substrate;
a gate insulation layer disposed on the active layer;
a first gate pattern disposed on the gate insulation layer;
an interlayer insulation layer disposed on the first gate pattern;
a second gate electrode disposed on the interlayer insulation layer and connected to the first gate pattern through a contact hole of the interlayer insulation layer;
a source electrode connected to a portion of the active layer; and
a drain electrode connected to another portion of the active layer,
wherein the active layer includes a first area including a dopant material,
wherein the first gate pattern includes a second area not overlapping the first area and a second subarea overlapping the first area, and
wherein the concentration of oxygen vacancies in the second area is greater than the concentration of oxygen vacancies in the second sub area.

16. The display device of claim 15, wherein the second area is connected to the second gate electrode.

17. The display device of claim 15, wherein the first gate pattern is formed of an oxide semiconductor material, and
wherein the second area is an area in which the oxide semiconductor material is rendered conductive.

18. The display device of claim 15, wherein an area of the active layer other than the first area has an area corresponding to the second area.
